(19) United States
(12) Patent Application Publication
(10) Pub. No.: US 2023/0074124 A1
(43) Pub. Date: Mar. 9, 2023

(54) DISPLAY DEVICE AND ELECTRONIC DEVICE INCLUDING THE SAME

(71) Applicant: Samsung Display Co., Ltd., Yongin-si (KR)

(72) Inventors: Donghwan Shim, Yongin-si (KR); Juhoon Kang, Yongin-si (KR); Sunmi Kang, Yongin-si (KR); Hyungkeun Park, Yongin-si (KR); Seokhyun Lim, Yongin-si (KR); Joohee Jeon, Yongin-si (KR)

(21) Appl. No.: 17/879,672

(22) Filed: Aug. 2, 2022

(30) Foreign Application Priority Data
Sep. 7, 2021 (KR) 10-2021-0118960

(51) Int. Cl. H01L 27/32; H01L 51/52

(52) U.S. Cl. CPC H01L 27/3276; H01L 51/5275; H01L 27/3262

(57) ABSTRACT

A display device includes: a substrate including a first area, a second area, and a third area; a first pixel circuit in the first area, and a first display element connected to the first pixel circuit; a second display element in the second area; a second pixel circuit in the third area; a connection wiring between the substrate and the second display element and connecting the second display element to the second pixel circuit; a first conductive layer in the first area; and a first protective layer including a same material as the connection wiring and on the first conductive layer.

### CROSS-REFERENCE TO RELATED APPLICATION

The present application claims priority to and the benefit of Korean Patent Application No. 10-2021-0118960, filed on Sep. 7, 2021, in the Korean Intellectual Property Office, the entire disclosure of which is incorporated herein by reference.

### BACKGROUND

### 1. Field

Aspects of one or more embodiments relate to display devices and electronic devices including the display devices.

### 2. Description of the Related Art

Display devices are devices for visually displaying data. Recently, the uses of display devices have diversified. Furthermore, as the thickness and weight of display devices decrease, the range of use of display devices is expanding.

As a method to expand the area occupied by a display area and simultaneously add various functions, display devices in which functions other than image display are added in the display area are continuously being researched.

The above information disclosed in this Background section is only for enhancement of understanding of the background and therefore the information discussed in this Background section does not necessarily constitute prior art.

### SUMMARY

Aspects of one or more embodiments relate to display devices and electronic devices including the display devices, and for example, to display devices in which a display area is expanded to display an image even in an area where components that are electronic elements are arranged, and electronic devices including the display devices.

Aspects of one or more embodiments include display devices, in which image display is possible even in an area where electronic components are arranged, and deterioration of performance of electronic components is prevented or reduced, and manufacturing methods thereof. However, such a characteristic is merely illustrative, and the scope of embodiments according to the present disclosure is not limited thereby.

Additional aspects will be set forth in part in the description which follows and, in part, will be apparent from the description, or may be learned by practice of the presented embodiments of the disclosure.

According to one or more embodiments, a display device includes a substrate including a first display area, a second display area, and a peripheral area, a first pixel circuit arranged in the first display area and a first display element connected to the first pixel circuit, a second display element arranged in the second display area, a second pixel circuit arranged in the peripheral area, a connection wiring arranged between the substrate and the second display element and connecting the second display element to the second pixel circuit, a first conductive layer arranged in the first display area, and a first protective layer including a same material as the connection wiring and arranged on the first conductive layer.

According to some embodiments, the display device may further include a second conductive layer arranged in the first display area and arranged on the same layer as the first conductive layer, an insulating layer covering the first conductive layer and the second conductive layer, and a third conductive layer arranged on the insulating layer and connected to the first protective layer through a first contact hole defined in the insulating layer.

According to some embodiments, the first contact hole may overlap the first protective layer.

According to some embodiments, the display device may further include a second protective layer including the same material as the connection wiring and arranged on the second conductive layer.

According to some embodiments, the area of a lower surface of the first protective layer may be the same as the area of an upper surface of the first conductive layer.

According to some embodiments, the first protective layer may cover a side surface of the first conductive layer.

According to some embodiments, the display device may further include an organic insulating layer arranged above the connection wiring, and a phase compensation layer arranged below the connection wiring, wherein a refractive index of the phase compensation layer may be less than a refractive index of the organic insulating layer.

According to some embodiments, the phase compensation layer may be patterned in a shape of the connection wiring.

According to some embodiments, the thickness of the phase compensation layer may be greater than the thickness of the connection wiring.

According to some embodiments, the display device may further include a pattern inorganic layer arranged below the first conductive layer, wherein the pattern inorganic layer includes the same material as the phase compensation layer.

According to some embodiments, the area of the first protective layer may be less than the area of the first conductive layer and greater than the area of a lower surface of the first contact hole.

According to some embodiments, the first protective layer may be patterned in a shape of the first conductive layer.

According to some embodiments, the display device may further include a second conductive layer arranged in the first display area and arranged on the same layer as the first conductive layer, and a second protective layer arranged on the second conductive layer, wherein the second protective layer may be patterned in a shape of the second conductive layer.

According to some embodiments, the thickness of the first protective layer may be less than the thickness of the first conductive layer.

According to some embodiments, an electronic device includes a display device including a first display area, a second display area, and a peripheral area, and a component arranged below the display device to correspond to the second display area, wherein the display device includes a substrate, a first pixel circuit arranged in the first display area and a first display element connected to the first pixel circuit, a second display element arranged on the second display area, a second pixel circuit arranged on the peripheral area, a connection wiring arranged between the substrate and the second display element and connecting the second display element to the second pixel circuit, a first conductive layer arranged in the first display area, and a first protective layer including the same material as the connection wiring and arranged on the first conductive layer.

According to some embodiments, the electronic device may further include a second conductive layer arranged in the first display area and arranged in the same layer as the first conductive layer, an insulating layer covering the first conductive layer and the second conductive layer, and a third conductive layer arranged on the insulating layer and connected to the first protective layer through a first contact hole defined in the insulating layer.

According to some embodiments, the first contact hole may overlap the first protective layer.

According to some embodiments, the electronic device may further include a second protective layer including the same materials as the connection wiring and arranged on the second conductive layer.

According to some embodiments, the area of a lower surface of the first protective layer may be the same as the area of an upper surface of the first conductive layer.

According to some embodiments, the electronic device may further include an organic insulating layer arranged above the connection wiring, and a phase compensation layer arranged below the connection wiring, wherein a refractive index of the phase compensation layer may be less than a refractive index of the organic insulating layer.

### BRIEF DESCRIPTION OF THE DRAWINGS

The above and other aspects, features, and characteristics of certain embodiments of the disclosure will be more apparent from the following description, taken in conjunction with the accompanying drawings, in which:

FIG. 1 is a schematic perspective view of an electronic device according to some embodiments;

FIG. 2 is a schematic cross-sectional view of part of an electronic device according to some embodiments;

FIGS. 3A and 3B are schematic plan views of part of a display device according to some embodiments;

FIG. 4 is a schematic plan view showing an arrangement of a partial area of a display device according to some embodiments;

FIG. 5 is a schematic cross-sectional view of part of the display device of FIG. 4;

FIG. 6 is a schematic cross-sectional view of part of the display device of FIG. 4;

FIG. 7 is a schematic cross-sectional view of part of a display device according to some embodiments;

FIG. 8 is a schematic cross-sectional view of part of a display device according to some embodiments;

FIGS. 9A and 9B are plan views showing an arrangement relationship of a first conductive layer, a second conductive layer, a first protective layer, and a second protective layer that are arranged in a first display area, according to some embodiments; and

FIGS. 10A to 10E are schematic cross-sectional views showing a process of manufacturing a display device according to some embodiments.

### DETAILED DESCRIPTION

Reference will now be made in more detail to aspects of some embodiments, which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to the present embodiments, and particular embodiments will be illustrated in the drawings and described in the detailed description section. The effect and features of the present embodiments, and a method to achieve the same, will be clearer referring to the detailed descriptions below with the drawings. However, the present embodiments may be implemented in various forms, not by being limited to the embodiments presented below.

Hereinafter, aspects of some embodiments will be described in more detail with reference to the accompanying drawings, and in the description with reference to the drawings, the same or corresponding constituents are indicated by the same reference numerals and redundant descriptions thereof are omitted.

It will be understood that although the terms “first,” “second,” etc. may be used herein to describe various components, these components should not be limited by these terms. These components are only used to distinguish one component from another.

As used herein, the singular forms are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or component is referred to as being “formed on” another layer, region, or component, it can be directly or indirectly formed on the other layer, region, or component. That is, for example, intervening layers, regions, or components may be present.

Sizes of components in the drawings may be exaggerated for convenience of explanation. For example, because sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

In the specification, the expression such as “A and/or B” may include A, B, or A and B. Furthermore, the expression such as “at least one of A and B” may include A, B, or A and B.

It will be understood that when a layer, region, or component is referred to as being “connected to” another layer, region, or component, it can be directly connected to the other layer, region, or component or indirectly connected to the other layer, region, or component via intervening layers, regions, or components. For example, in the specification, when a layer, region, or component is referred to as being electrically connected to another layer, region, or component, it can be directly electrically connected to the other layer, region, or component or indirectly electrically connected to the other layer, region, or component via intervening layers, regions, or components.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

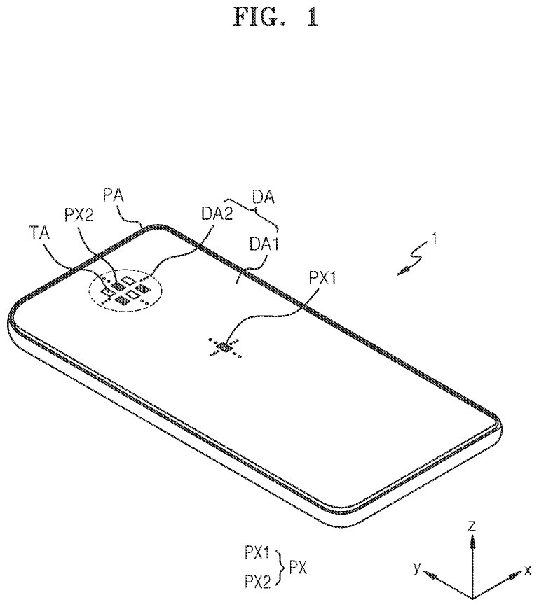

FIG. 1 is a schematic perspective view of an electronic device 1 according to some embodiments.

Referring to FIG. 1, the electronic device 1 may include a display area DA and a peripheral area PA arranged outside of (e.g., outside a footprint of) the display area DA. The display area DA may include a first display area DA1 and a second display area DA2 adjacent to the first display area DA1. The electronic device 1 may display an image (or images) through an array of a plurality of pixels PX arranged in two-dimensions (e.g., in a matrix arrangement) in the display area DA. For example, a first image may be provided or displayed using light emitted from a plurality of first pixels PX1 arranged in the first display area DA1, and a second image may be provided using light emitted from a plurality of second pixels PX2 arranged in the second display area DA2. According to some embodiments, the first image and the second image may be parts of any one image provided through the display area DA of the electronic device 1. Alternatively, in some embodiments, the first image and the second image may be provided as images independent of each other. That is, according to some embodiments, pixels in the first display area DA1 and the second display area DA2 may work in coordination to display portions of an image, where the portion displayed in the first display area DA1 and the portion displayed in the second area DA2 collectively form a single or cohesive image. Additionally, the pixels in the first display area DA1 and the second display area DA2 may operate independently from the pixels in the other display area, such that different or distinct (i.e., independent) images are displayed in the different display areas.

As an example, FIG. 1 illustrates that one second display area DA2 is located in the first display area DA1. According to some embodiments, the electronic device 1 may have two or more second display areas DA2, and the shapes and sizes of a plurality of second display areas DA2 may be different from each other. When viewed from a direction approximately perpendicular (or normal) with respect to an upper surface (e.g., or a primary display surface) of the electronic device 1, the shape of the second display area DA2 may include various shapes such as a circle, an oval, a polygon such as a rectangle and the like, a star shape, a diamond shape, and the like. According to some embodiments, a ratio of the second display area DA2 to the display area DA may be less than a ratio of the first display area DA1 to the display area DA.

Although FIG. 1 illustrates that the second display area DA2 is arranged at the center of an upper side (+y direction) of the first display area DA1 having an about rectangle shape, when viewed from a direction approximately perpendicular to an upper surface of the electronic device 1 (e.g., when viewed in a plan view), the second display area DA2 may be arranged at the upper right side or upper left side of the first display area DA1 that is, for example, rectangular. Furthermore, the second display area DA2 may be arranged, as an example, inside the first display area DA1 as illustrated in FIG. 1, and may be entirely surrounded by the first display area DA1. In another example, the second display area DA2 may be arranged at one side of the first display area DA1 and partially surrounded by the first display area DA1. For example, the second display area DA2 is located in one corner portion of the first display area DA1 and surrounded by the first display area DA1.

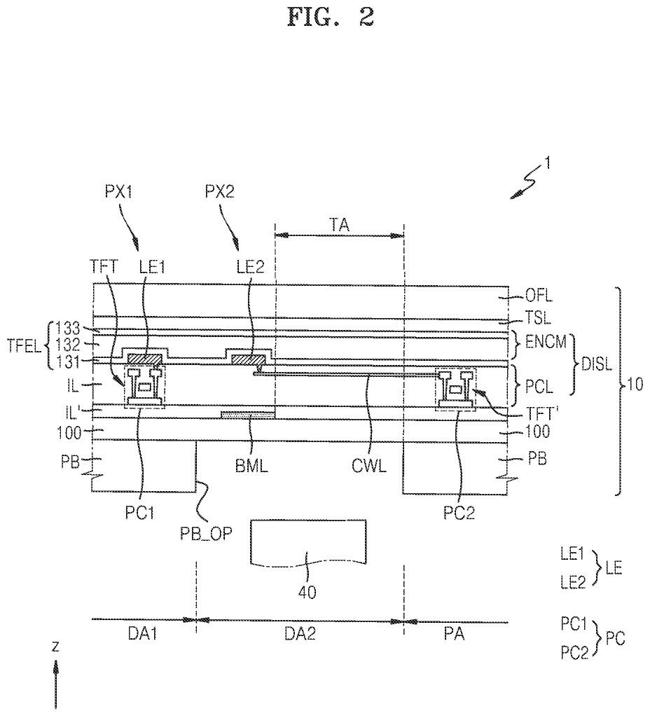

An electronic component 40 (see FIG. 2) may be arranged in the second display area DA2. The electronic component 40 may be arranged under a display device 10 (see FIG. 2) corresponding to the second display area DA2.

The electronic component 40 may be an electronic element using light or sound. For example, the electronic element may be a sensor such as a proximity sensor for measuring a distance, a sensor for recognizing part of a body of a user, for example, fingerprint, iris, face, and the like, a small lamp outputting light, an image sensor, for example, a camera, for capturing an image, and the like. An electronic element using light may use light of various wavelength bands such as visible light, infrared light, ultraviolet light, and the like. An electronic element using sound may use ultrasound or sound of another frequency band.

To allow the electronic component 40 to relatively smoothly function, the second display area DA2 may include a transmission area TA that enables light or/and sound (or other signals in a wireless spectrum) to be transmitted therethrough, and the like output from the electronic component 40 to the outside or proceeding toward the electronic component 40 from the outside. The transmission area TA, which is an area that transmits light, may be an area where the pixel PX is not arranged. In the electronic device 1 according to some embodiments, when light is transmitted through the second display area DA2 including the transmission area TA, light transmittance may be about 10% or more, particularly 25% or more, 40% or more, 50% or more, 85% or more, or 90% or more.

As the second display area DA2 include the transmission area TA, an array of the first pixels PX1 arranged in the first display area DA1 and an array of the second pixels PX2 arranged in the second display area DA2 may be different from each other. For example, the transmission area TA may be arranged between the second pixels PX2 neighboring each other of the second pixels PX2.

In this case, due to the relatively lower number or density of pixels in the second display area DA2 relative to the number or density of the pixels in the first display area DA1, the second display area DA2 may have a resolution that is less than that of the first display area DA1. In other words, as the second display area DA2 includes the transmission area TA, the number of the second pixels PX2 to be arranged per equal area in the second display area DA2 may be less than the number of the first pixels PX1 to be arranged per equal area in the first display area DA1. For example, the resolution of the second display area DA2 may be about ½, ⅜, ⅓, ¼, 2/9, ⅛, 1/9, 1/16, and the like of the resolution of the first display area DA1. For example, the resolution of the first display area DA1 may be about 400 ppi or more, and the resolution of the second display area DA2 may be about 200 ppi or about 100 ppi.

The peripheral area PA, as a non-display area that does not display an image, may surround entirely or partially the display area DA. For example, the peripheral area PA may surround entirely or partially the first display area DA1 and/or the second display area DA2. A driver for providing an electrical signal or power to the display area DA, and the like may be arranged in the peripheral area PA. A pad that is an area, to which an electronic device, a printed circuit board, and the like is electrically connected, may be arranged in the peripheral area PA. In this specification, the peripheral area PA may be a third area. Also, the first display area DA1 may be a first area and the second display area DA2 may be a second area.

In the following description, for convenience of explanation, a case in which the electronic device 1 is sued for a smart phone is described, but the electronic device 1 according to some embodiments is not limited thereto. The electronic device 1 may be applied not only to portable electronic devices such as mobile phones, smart phones, tablet personal computers (PC), mobile communication terminals, electronic organizers, electronic books, portable multimedia players (PMP), navigation devices, ultra mobile PCs (UMPC), and the like, but to various products such as televisions, notebook computers, monitors, billboards, Internet of things (IOT), and the like. Furthermore, the electronic device 1 according to some embodiments may be applied to wearable devices such as smart watches, watch phones, glasses type displays, and head mounted displays (HMD). Furthermore, the electronic device 1 according to some embodiments may be applied to instrument panels of vehicles, center information displays (CID) arranged on center fascia or dashboards of vehicles, room mirror displays replacing side mirrors of vehicles, display screens arranged on a rear surface of a front seat as an entertainment for rear seats of vehicles.

Furthermore, in the following description, although the electronic device 1 is described as including an organic light-emitting diode OLED as a display element, the electronic device 1 according to some embodiments is not limited thereto. According to some embodiments, the electronic device 1 may be a light-emitting display device including an inorganic light-emitting diode, that is, an inorganic light-emitting display device. According to some embodiments, the electronic device 1 may be a quantum dot light-emitting display device.

FIG. 2 is a schematic cross-sectional view of part of the electronic device 1 according to some embodiments.

Referring to FIG. 2, the electronic device 1 may include a display device 10 and the electronic component 40 arranged to overlap the display device 10. A cover window for protecting the display device 10 may be further arranged above the display device 10.

The display device 10 may include the first display area DA1 for displaying a first image and the second display area DA2 for displaying a second image and overlapping the electronic component 40. The display device 10 may include a substrate 100, a display layer DISL on the substrate 100, a touchscreen layer TSL, an optical functional layer OFL, and a panel protection member PB arranged below the substrate 100.

The display layer DISL may include a pixel circuit layer PCL including a pixel circuit PC, a display element layer including a display element LE, and an encapsulation member ENCM. As an example, the encapsulation member ENCM may be a thin film encapsulation layer TFEL or an encapsulation substrate. Insulating layers IL and IL′ may be arranged in the display layer DISL between the substrate 100 and the display layer DISL.

The substrate 100 may include an insulating material such as glass, quartz, polymer resin, and the like. The substrate 100 may be a rigid substrate or a flexible substrate capable of bending, folding, rolling, and the like.

A plurality of first pixel circuits PC1 and a plurality of first display elements LE1 electrically connected to the first pixel circuits PC1 may be arranged in the first display area DA1 of the display device 10. The first pixel circuit PC1 may include at least one thin film transistor TFT and control light-emitting of the first display element LE1. The first display element LE1 may emit light through an emission area, and the emission area may be defined as the first pixel PX1. In other words, the first pixel PX1 may be implemented by the light-emitting of the first display element LE1.

A plurality of second display elements LE2 may be arranged in the second display area DA2 of the display device 10. According to some embodiments, a second pixel circuit PC2 for controlling the light-emitting of the second display element LE2 may be arranged not in the second display area DA2, but in the peripheral area PA. According to some embodiments, the second pixel circuit PC2 may be positioned in various locations, for example, in a portion of the first display area DA1, between the first display area DA1 and the second display area DA2, and the like.

The second pixel circuit PC2 may include at least one thin film transistor TFT′ and may be electrically connected to the second display element LE2 by a connection wiring CWL. As an example, the connection wiring CWL may include a transparent conductive material. The second pixel circuit PC2 may control the light-emitting of the second display element LE2. The second display element LE2 may emit light through an emission area, and the emission area may be defined as the second pixel PX2. In other words, the second pixel PX2 may be implemented by the light-emitting of the second display element LE2.

Furthermore, in the second display area DA2, an area where the second display element LE2 is not arranged may include the transmission area TA. The transmission area TA may be an area that transmits light/signals emitted from the electronic component 40 arranged corresponding to the second display area DA2 or light/signals incident on the electronic component 40.

The connection wiring CWL that electrically connects the second pixel circuit PC2 to the second display element LE2 may be arranged in the transmission area TA. The connection wiring CWL may include a transparent conductive material having high light transmittance, and thus, even when the connection wiring CWL is arranged in the transmission area TA, deterioration of the light transmittance of the transmission area TA may be prevented or reduced.

Furthermore, according to some embodiments, as the second pixel circuit PC2 is not arranged in the second display area DA2, the area of the transmission area TA may be sufficiently obtained so that the light transmittance of the second display area DA2 may be increased.

The display element LE may be covered with the thin film encapsulation layer TFEL or the encapsulation substrate. In some embodiments, the thin film encapsulation layer TFEL may include, as illustrated in FIG. 2, at least one inorganic encapsulation layer and at least one organic encapsulation layer. According to some embodiments, the thin film encapsulation layer TFEL may include a first inorganic encapsulation layer 131 and a second inorganic encapsulation layer 133, and an organic encapsulation layer 132 therebetween.

When the display element LE is encapsulated by the encapsulation substrate, the encapsulation substrate may be arranged to face the substrate 100 with the display element LE therebetween. A gap may be present between the encapsulation substrate and the display element layer LEL. The encapsulation substrate may include glass. A sealant formed of frit and the like may be arranged between the substrate 100 and the encapsulation substrate, and the sealant may be arranged in the above-described peripheral area PA. The sealant arranged in the peripheral area PA may surround the display area DA and prevent or reduce infiltration of moisture through a side surface.

The touchscreen layer TSL may obtain coordinates information according to an external input, for example, a touch event. The touchscreen layer TSL may include a touch electrode and touch wirings connected to the touch electrode. The touchscreen layer TSL may sense an external input by a self-capacitance method or a mutual capacitance method.

The touchscreen layer TSL may be formed on the thin film encapsulation layer TFEL. Alternatively, the touchscreen layer TSL may be separately formed on a touch substrate and then coupled to the thin film encapsulation layer TFEL through an adhesive layer such as an optically clear adhesive OCA. According to some embodiments, the touchscreen layer TSL may be directly formed on the thin film encapsulation layer TFEL. In this case, the adhesive layer may not be provided between the touchscreen layer TSL and the thin film encapsulation layer TFEL.

The optical functional layer OFL may include an antireflection layer. The antireflection layer may reduce reflectivity of light (external light) incident on the electronic device 1 from the outside.

In some embodiments, the optical functional layer OFL may include a polarization film. In some embodiments, the optical functional layer OFL may be provided as a filter plate including a black matrix and color filters.

The panel protection member PB may be attached to a lower surface of the substrate 100 to support and protect the substrate 100. The panel protection member PB may include an opening PB_OP corresponding to the second display area DA2. As the panel protection member PB includes the opening PB_OP, the light transmittance of the second display area DA2 may be improved. The panel protection member PB may include polyethylene terephthalate (PET) or polyimide (PI).

The area of the second display area DA2 may be greater than the area in which the electronic component 40 is arranged. Accordingly, the area of the opening PB_OP in the panel protection member PB may not match the area of the second display area DA2.

The electronic components 40 may be arranged in the second display area DA2. In this case, the electronic components 40 may have different functions. For example, the electronic components 40 may include at least two of a camera (image pickup device), a solar cell, a flash, a proximity sensor, an illuminance sensor, and an iris sensor.

According to some embodiments, a bottom metal layer BML may be arranged in the second display area DA2. The bottom metal layer BML may be arranged to overlap the second display element LE2 between the substrate 100 and the second display element LE2. The bottom metal layer BML may include a light shield material and prevent or reduce instances of external light reaching the second display element LE2.

According to some embodiments, the bottom metal layer BML may be formed corresponding to the whole of the second display area DA2, and may include a hole corresponding to the transmission area TA. In this case, the hole may have various shapes such as a polygonal shape, a circular shape, an amorphous shape, and the like to adjust the diffraction properties of the external light.

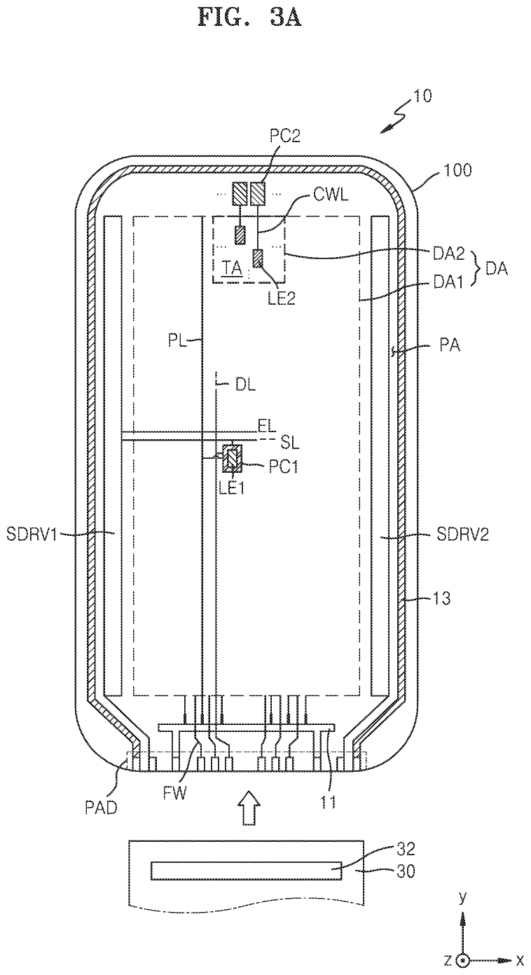

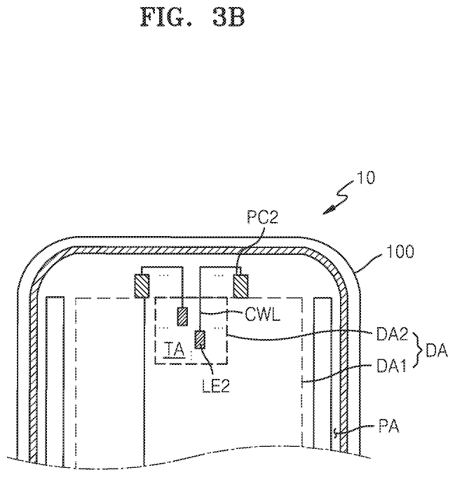

FIGS. 3A and 3B are schematic plan views of part of a display device according to some embodiments.

Referring to FIG. 3A, various constituent elements forming the display device 10 may be arranged on the substrate 100. The display device 10 may include the display area DA and the peripheral area PA surrounding the display area DA. The display area DA may include the first display area DA1 where the first image is displayed and the second display area DA2 including the transmission area TA and where the second image is displayed. The second image may form one whole image with the first image, and the second image may be an image independent of the first image.

The first display element LE1, for example, an organic light-emitting diode OLED, may be arranged in the first display area DA1. The first display element LE1 may emit light of a certain color through the first pixel PX1 (see FIG. 1). In other words, the first pixel PX1 may be implemented by the first display element LE1, and the first pixel PX1 may be a sub-pixel. The first display element LE1 may emit, for example, red, green, blue, or white light. The first pixel circuit PC1 for driving the first display element LE1 may be arranged in the first display area DA1, and may be electrically connected to the first display element LE1. The first pixel circuit PC1 may be arranged to overlap, as an example, the first display element LE1.

The second display area DA2, as illustrated in FIG. 3A, may be located at one side of the entire display area DA and partially surrounded by the first display area DA1. The second display element LE2, for example, an organic light-emitting diode OLED, may be arranged in the second display area DA2. The second display element LE2 may emit light of a certain color through the second pixel PX2 (see FIG. 1). In other words, the second pixel PX2 may be implemented by the second display element LE2, and the second pixel PX2 may be a sub-pixel. The second display element LE2 may emit, for example, red, green, blue, or white light.

The second pixel circuit PC2 for driving the second display element LE2 may be arranged in the peripheral area PA and electrically connected to the second display element LE2. As an example, the second pixel circuit PC2 may be arranged in the peripheral area PA adjacent to the second display area DA2. In other words, the second pixel circuit PC2 may be arranged adjacent to an outer side of the second display area DA2. As illustrated in FIG. 3A, when the second display area DA2 is arranged at the upper side of the entire display area DA, the second pixel circuit PC2 may be arranged at the upper side of the peripheral area PA. The second pixel circuit PC2 and the second display element LE2 may be electrically connected to the connection wiring CWL that extends, for example, in a y direction. The connection wiring CWL may extend, for example, in the same direction as a direction in which the data line DL extends.

The second display area DA2 may include the transmission area TA. The transmission area TA may be arranged to surround the second display elements LE2. Alternatively, the transmission area TA may be arranged in the form of a grating with the second display elements LE2.

Each of the first pixel circuit PC1 and the second pixel circuit PC2 may be electrically connected to outer circuits arranged in the peripheral area PA. A first scan driving circuit SDRV1, a second scan driving circuit SDRV2, a pad portion PAD, a driving voltage supply line 11, and a common voltage supply line 13 may be arranged in the peripheral area PA.

The first scan driving circuit SDRV1 may apply, via a scan line SL, a scan signal to each of the first pixel circuits PC1 that drive the first display elements LE1. The first scan driving circuit SDRV1 may apply an emission control signal to each of the first pixel circuits PC1 via an emission control line EL. The second scan driving circuit SDRV2 may be located at the opposite side to the first scan driving circuit SDRV1 with respect to the first display area DA1, and may be arranged approximately parallel to the first scan driving circuit SDRV1. Some of the first pixel circuits PC1 in the first display area DA1 may be electrically connected to the first scan driving circuit SDRV1, and the other may be electrically connected to the second scan driving circuit SDRV2.

In some embodiments, each of the second pixel circuit PC2 that drive the second display elements LE2 may also receive the scan signal and the emission control signal from the first scan driving circuit SDRV1 and/or the second scan driving circuit SDRV2, via separate wirings extending from the scan line SL and/or the emission control line EL.

The pad portion PAD may be arranged at one side of the substrate 100. The pad portion PAD is exposed, not covered by an insulating layer, and connected to a display circuit board 30. A display driving unit 32 may be arranged on the display circuit board 30.

The display driving unit 32 may generate a control signal that is delivered to the first scan driving circuit SDRV1 and the second scan driving circuit SDRV2. The display driving unit 32 may generate a data signal, and the data signal may be delivered to the first pixel circuits PC1 via a fan-out wiring FW and the data line DL connected to the fan-out wiring FW. Furthermore, according to some embodiments, the data signal may be delivered to the second pixel circuits PC2 via the data line DL or separate wirings extending from the data line DL.

The display driving unit 32 may supply a driving voltage ELVDD to the driving voltage supply line 11, and a common voltage ELVSS to the common voltage supply line 13. The driving voltage ELVDD may be applied to the first pixel circuit PC1 via a driving voltage line PL connected to the driving voltage supply line 11, and according to some embodiments, the driving voltage ELVDD may be applied to the second pixel circuits PC2 via the driving voltage supply line 11 or separate wirings extending from the driving voltage supply line 11. The common voltage ELVSS may be connected to the common voltage supply line 13 and applied to a counter electrode of each of the first display element LE1 and the second display element LE2.

The driving voltage supply line 11 may extend below the first display area DA1, for example, in an x direction. The common voltage supply line 13 may have a loop shape having one open side and may partially surround the first display area DA1.

Referring to FIG. 3B, the second pixel circuit PC2 may be arranged in the peripheral area PA adjacent to the first display area DA1. The second pixel circuit PC2 may be arranged adjacent to the outer side of the first display area DA1. In this case, the second pixel circuit PC2 and the second display element LE2 may be electrically connected to each other by, for example, the connection wiring CWL extending in the x direction and the y direction. The connection wiring CWL may extend, for example, in the same direction as a direction in which the scan line SL extends and/or the same direction as a direction in which the data line DL extends.

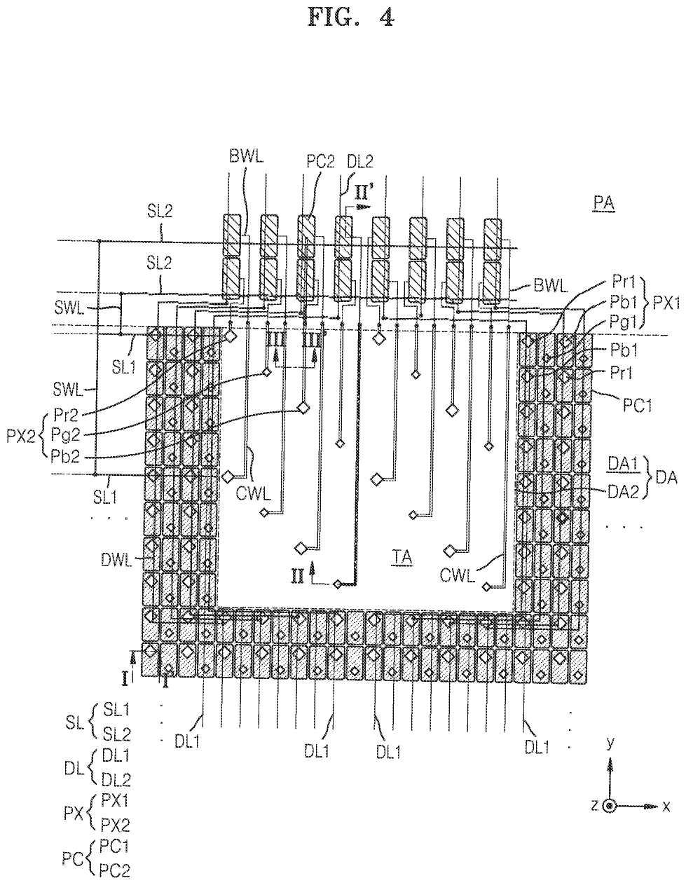

FIG. 4 is a schematic plan view showing an arrangement of a partial area of the display device 10 according to some embodiments. FIG. 4 illustrates the second display area DA2, the first display area DA1 around second display area DA2, and part of the peripheral area PA, and shows an arrangement of the pixels PX and the pixel circuits PC.

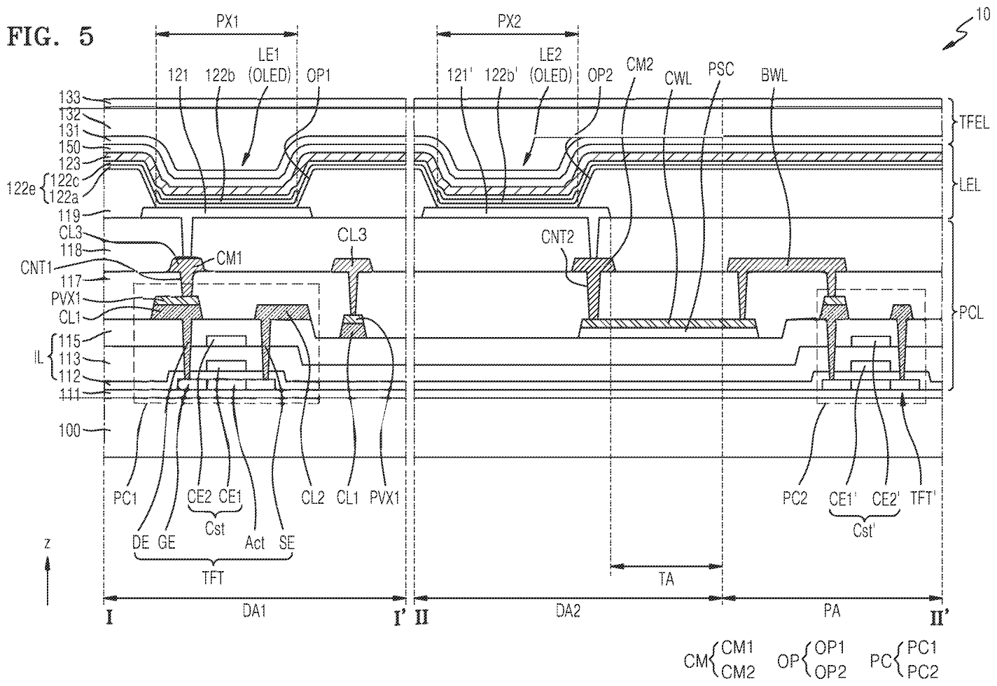

Referring to FIG. 4, the first pixels PX1 may be arranged in the first display area DA1. In the specification, the pixel PX may mean a sub-pixel as a minimum unit for implementing an image, and may be defined as an emission area from which the display element LE emits light. When the display element LE is an organic light-emitting diode OLED, the emission area may be defined by an opening of a pixel defining layer, which is described in more detail below with reference to FIG. 5.

Each of the first pixels PX1 may emit any one of red, green, blue, and white light. As an example, the first pixels PX1 may include a first red pixel Pr1, a first green pixel Pg1, and a first blue pixel Pb1.

The first pixels PX1 may be arranged in various arrangements or configuration, for example, Pentile® type of arrangement as illustrated in FIG. 4. For example, among vertexes of a virtual rectangle having the center portion of the first green pixel Pg1 as the center point of the rectangle, the first red pixels Pr1 may be arranged diagonally at the first and third vertexes facing each other, and the first blue pixels Pb1 may be arranged at the other vertexes that are the second and fourth vertexes. The size of the first green pixel Pg1 may be less than the size of each of the first red pixel Pr1 and the first blue pixel Pb1. Through the above arrangement, a high resolution may be obtained with a small number of pixels. The disclosure is not limited thereto, and the first pixels PX1 may be arranged in various forms such as stripe type, mosaic arrangement type, delta arrangement type, and the like.

The first pixel circuits PC1 may be arranged in the first display area DA1 to overlap the first pixels PX1. The first pixel circuits PC1 may be arranged in a matrix form, for example, forming rows and columns in the x direction and the y direction.

The second pixels PX2 may be arranged in the second display area DA2. Each of the second pixels PX2 may emit any one of red, green, blue, and white light. As an example, the second pixels PX2 may include a second red pixel Pr2, a second green pixel Pg2, and a second blue pixel Pb2.

The second pixels PX2 may be arranged in various types in the second display area DA2. According to some embodiments, some second pixels PX2 may gather to form a pixel group, and in the pixel group, the second pixels PX2 may be arranged in various types such as Pentile® type, a stripe type, a mosaic arrangement type, a delta arrangement type, and the like.

As illustrated in FIG. 4, the second pixels PX2 may be distributed and arranged in the second display area DA2. In other words, a distance between the second pixels PX2 may be greater than a distance between the first pixels PX1. Accordingly, as described above, the number of the second pixels PX2 to be arranged per equal area in the second display area DA2 may be less than the number of the first pixels PX1 to be arranged per equal area in the first display area DA1. An area of the second display area DA2 in which the second pixels PX2 are not arranged may include the transmission area TA having high light transmittance.

The second pixel circuits PC2 may be arranged in the peripheral area PA and may not overlap the second pixels PX2. As the second pixel circuits PC2 is not arranged in the second display area DA2, the second display area DA2 may secure the transmission area TA that is relatively large. Furthermore, wirings for delivering a constant voltage and signals to the second pixel circuit PC2 may not be arranged in the second display area DA2, and the second pixels PX2 may be freely arranged without considering the arrangement of the wirings.

In order for the second pixel circuits PC2 arranged in the peripheral area PA to drive the second pixel PX2 arranged in the second display area DA2, the connection wiring CWL and/or a bridge wiring BWL may be provided. The connection wiring CWL and/or the bridge wiring BWL may include a conductive material, and may electrically connect between the second pixel circuit PC2 and the second pixel PX2. As an example, the second pixel circuit PC2 may be electrically connected to the second pixel PX2 through the connection wiring CWL. In another example, the second pixel circuit PC2 may be electrically connected to the second pixel PX2 through the connection wiring CWL and the bridge wiring BWL electrically connected to each other. The electrical connection to the second pixel PX2 may mean the electrical connection to the pixel electrode of the second display element LE2 (see FIGS. 3A and 3B) implementing the second pixel PX2. In the following description, for convenience of explanation, a case of including both of the connection wiring CWL and the bridge wiring BWL is described.

The connection wiring CWL may be arranged at least part of the second display area DA2 and may include a transparent conductive material. A connection wiring TWL may include, for example, a transparent conducting oxide (TCO). For example, the connection wiring TWL may include a conductive oxide such as indium tin oxide (ITO), indium zinc oxide (IZO), zinc oxide (ZnO), indium oxide (In₂O₃), indium gallium oxide (IGO), indium zinc gallium oxide (IZGO), or aluminum zinc oxide (AZO). As such, even when the connection wiring CWL is arranged in the transmission area TA of the second display area DA2, the deterioration of light transmittance of the transmission area TA may be reduced.

The bridge wiring BWL may be arranged in the peripheral area PA. The bridge wiring BWL may have one end portion electrically connected to the connection wiring CWL via a contact hole and the other end portion electrically connected to the second pixel circuit PC2.

The bridge wiring BWL may include a metal material. For example, the bridge wiring BWL may include a metal material including molybdenum (Mo), aluminum (Al), copper (Cu), titanium (Ti), and the like, and may be formed in a multilayer or single layer including the above material.

The bridge wiring BWL may have conductivity higher than the connection wiring CWL. As the bridge wiring BWL is arranged in the peripheral area PA, there is no need to secure light transmittance, and thus, a material having lower light transmittance and higher conductivity than the connection wiring CWL may be employed. Accordingly, a resistance value between may be reduced.

The scan line SL may include a first scan line SL1 connected to the first pixel circuits PC1 and a second scan line SL2 connected to the second pixel circuits PC2. The first scan line SL1 may extend in the x direction and may be connected to the first pixel circuits PC1 arranged in the same row. The first scan line SL1 may not be arranged in the second display area DA2. In other words, the first scan line SL1 may be discontinued in the second display area DA2. In this case, the first scan line SL1 arranged on the left of the second display area DA2 may receive a scan signal from the first scan driving circuit SDRV1 (see FIG. 3A), and the first scan line SL1 arranged on the right of the second display area DA2 may receive a scan signal from the second scan driving circuit SDRV2 (see FIG. 3A).

The second scan line SL2 may be connected to the second pixel circuit PC2 for driving the second pixel PX2 arranged in the same row among the second pixel circuits PC2 arranged in the same row.

The first scan line SL1 and the second scan line SL2 may be connected by a scan connection line SWL, the same signal may be applied to the pixel circuits PC that drive the first pixel PX1 and the second pixel PX2 which are arranged in the same row.

The scan connection line SWL may be arranged on a layer different from a layer on which the first scan line SL1 and the second scan line SL2 are arranged, and thus the scan connection line SWL may be connected to each of the first scan line SL1 and the second scan line SL2 via a contact hole. The scan connection line SWL may be arranged in the peripheral area PA.

The data line DL may include a first data line DL1 connected to the first pixel circuits PC1 and a second data line DL2 connected to the second pixel circuits PC2. The first data line DL1 may extend in the y direction and may be connected to the first pixel circuits PC1 arranged in the same row. The second data line DL2 may extend in the y direction and may be connected to the second pixel circuits PC2 arranged in the same row.

The first data line DL1 and the second data line DL2 may be arranged apart from each other with the second display area DA2 therebetween. The first data line DL1 and the second data line DL2 may be connected to each other by a data connection line DWL, and the same signal may be applied to the pixel circuits PC that drive the first pixel PX1 and the second pixel PX2 arranged in the same row.

The data connection line DWL may be arranged to detour the second display area DA2. The data connection line DWL may be arranged to overlap the first pixel circuits PC1 arranged in the first display area DA1. As the data connection line DWL is arranged in the first display area DA1, there is no need to secure a separate space where the data connection line DWL is arranged, and thus a dead space area may be reduced.

The data connection line DWL may be arranged on a layer different from a layer on which the first data line DL1 and the second data line DL2 are arranged, and thus the data connection line DWL may be connected to each of the first data line DL1 and the second data line DL2 via a contact hole.

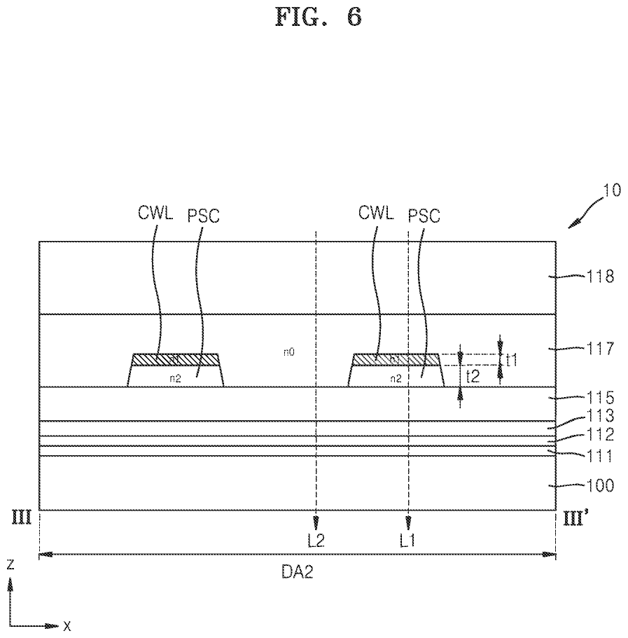

FIGS. 5 and 6 are schematic cross-sectional views of part of the display device 10 of FIG. 4, in which FIG. 5 is a cross-sectional view of parts of the display device 10 taken along the lines I-I′ and II-II′ of FIG. 4, and FIG. 6 is a cross-sectional view of a part of the display device 10 taken along the line III-Ill′ of FIG. 4.

Referring to FIG. 5, the first display area DA1 may include the first pixel PX1, and the second display area DA2 may include the second pixel PX2 and the transmission area TA. The first pixel circuit PC1 including a plurality of thin film transistors TFT and a storage capacitor Cst, and the first display element LE1 electrically connected to the first pixel circuit PC1 may be arranged in the first display area DA1. The second display element LE2 may be arranged in the second display area DA2. The second pixel circuit PC2 including a plurality of thin film transistors TFT′ and a storage capacitor Cst′ may be arranged in the peripheral area PA. The second pixel circuit PC2 may be electrically connected to the second display element LE2 through the connection wiring CWL.

According to some embodiments, a protective layer PVX including the same material as that of the connection wiring CWL may be arranged above a first conductive layer CL1 arranged in the first display area DA1.

Hereinafter, a structure in which components included in the display device 10 are stacked is described. The display device 10 may include a stack structure of the substrate 100, a buffer layer 111, the pixel circuit layer PCL, the display element layer LEL, and the thin film encapsulation layer TFEL.

The substrate 100 may include an insulating material such as glass, quartz, polymer resin, and the like. The substrate 100 may be a rigid substrate or a flexible substrate capable of bending, folding, rolling, and the like.

The buffer layer 111 may be arranged on the substrate 100, may reduce or block infiltration of foreign materials such as moisture or external air from under the substrate 100, and may provide a planarized surface to the substrate 100. The buffer layer 111 may include an inorganic material such as oxide or nitride, an organic material, or an organic/inorganic complex, and may have a single layer or multilayer structure of an inorganic material and an organic material. A barrier layer for blocking infiltration of external air may be further provided between the substrate 100 and the buffer layer 111. In some embodiments, the buffer layer 111 may include silicon oxide (SiO₂) or silicon nitride (SiNₓ).

The pixel circuit layer PCL may be arranged on the buffer layer 111, and may include the pixel circuit PC, a first gate insulating layer 112, a second gate insulating layer 113, an interlayer insulating layer 115, a first organic insulating layer 117, and a second organic insulating layer 118.

The thin film transistors TFT and TFT′ and the storage capacitors Cst and Cst′ may be arranged on the buffer layer 111. As the thin film transistor TFT′ and the storage capacitor Cst′ of the second pixel circuit PC2 may have a structure substantially the same as or similar to the thin film transistor TFT and the storage capacitor Cst of the first pixel circuit PC1, the descriptions on the thin film transistor TFT and the storage capacitor Cst of the first pixel circuit PC1 may replace the descriptions on the thin film transistor TFT′ and the storage capacitor Cst′ of the second pixel circuit PC2.

The thin film transistors TFT and TFT′ may include a semiconductor layer Act, a gate electrode GE, a source electrode SE, and a drain electrode DE. The thin film transistors TFT and TFT′ may be connected to the organic light-emitting diode OLED and may drive the organic light-emitting diode OLED.

The semiconductor layer Act may be arranged on the buffer layer 111 and may include poly silicon. According to some embodiments, the semiconductor layer Act may include amorphous silicon. According to some embodiments, the semiconductor layer Act may include an oxide of at least one material selected from the group consisting of indium (In), gallium (Ga), stannum (Sn), zirconium (Zr), vanadium (V), hafnium (Hf), cadmium (Cd), germanium (Ge), chromium (Cr), Ti, and zinc (Zn). The semiconductor layer Act may include a channel region, and a source region and a drain region that are doped with impurities.

The first gate insulating layer 112 may be provided to cover the semiconductor layer Act. The first gate insulating layer 112 may include an inorganic insulating material such as SiO₂, SiNₓ, SiOₓN_{y}, aluminum oxide (Al₂O₃), titanium oxide (TiO₂), tantalum oxide (Ta₂O₅), or hafnium oxide (HfO₂), and the like. The first gate insulating layer 112 may be a single layer or multilayer including the above-described inorganic insulating material.

The gate electrode GE is arranged on the first gate insulating layer 112 to overlap the semiconductor layer Act. The gate electrode GE may include Mo, Al, Cu, Ti, and the like and may be a single layer or multilayer. As an example, the gate electrode GE may be a single layer of Mo.

The second gate insulating layer 113 may cover the gate electrode GE. The second gate insulating layer 113 may include an inorganic insulating material such as SiO₂, SiNₓ, SiOₓN_{y}, Al₂O₃, TiO₂, Ta₂O₅, or HfO₂, and the like. The second gate insulating layer 113 may be a single layer or multilayer including the above-described inorganic insulating material.

The upper electrodes CE2 and CE2′ of the storage capacitors Cst and Cst′ may be arranged on the second gate insulating layer 113. The upper electrodes CE2 and CE2′ of the storage capacitors Cst and Cst′ may overlap the gate electrode GE thereunder. The gate electrode GE and the upper electrodes CE2 and CE2′ overlapping with the second gate insulating layer 113 therebetween may form the storage capacitors Cst and Cst′, respectively. In this state, the gate electrode GE may include the lower electrodes CE1 and CE1′ of the storage capacitors Cst and Cst′.

The upper electrodes CE2 and CE2′ may include Al, platinum (Pt), palladium (Pd), silver (Ag), magnesium (Mg), gold (Au), nickel (Ni), neodymium (Nd), iridium (Ir), chromium (Cr), calcium (Ca), Mo, Ti, tungsten (W), and/or Cu, and may be a single layer or multilayer including the above-described material.

The interlayer insulating layer 115 may cover the upper electrodes CE2 and CE2′. The interlayer insulating layer 115 may include an inorganic insulating material such as SiO₂, SiNₓ, SiOₓN_{y}, Al₂O₃, TiO₂, Ta₂O₅, or HfO₂, and the like. The interlayer insulating layer 115 may be a single layer or multilayer including the above-described inorganic insulating material.

The source electrode SE and the drain electrode DE may be arranged on the interlayer insulating layer 115. The source electrode SE and the drain electrode DE may include a conductive material including Mo, Al, Cu, Ti, and the like, and may be formed in a multilayer or single layer including the above material. As an example, the source electrode SE and the drain electrode DE may have a multilayer structure of Ti/Al/Ti.

The first organic insulating layer 117 may be arranged on the interlayer insulating layer 115, and may cover the source electrode SE and the drain electrode DE.

The first organic insulating layer 117 may include photosensitive polyimide or a siloxane organic material. For example, the first organic insulating layer 117 may include, as photosensitive polyimide, or general purpose polymer such as polyimide, polystyrene (PS), polycarbonate (PC), benzocyclobutene (BCB), hexamethyldisiloxane (HMDSO), or polymethylmethacrylate (PMMA), polymer derivatives having a phenolic group, acrylic polymer, imide-based polymer, arylether-based polymer, amide-based polymer, fluorine-based polymer, p-xylene-based polymer, vinyl alcohol-based polymer, and the like. Alternatively, the first organic insulating layer 117 may include, as a siloxane organic material, HMDSO, octamethyltrisiloxane, decamethyltetrasiloxane, dodecamethylpentasiloxane, and polydimethylsiloxanes.

The second organic insulating layer 118 may be arranged on the first organic insulating layer 117. The second organic insulating layer 118 may have a flat upper surface so that the pixel electrodes 121 and 121′ arranged thereabove are flat. The second organic insulating layer 118 may include a siloxane organic material having high light transmittance and planarization. The siloxane organic material may include HMDSO, octamethyltrisiloxane, decamethyltetrasiloxane, dodecamethylpentasiloxane, and polydimethylsiloxanes.

Alternatively, the second organic insulating layer 118 may include general purpose polymer such as photosensitive polyimide, polyimide, BCB, HMDSO, PMMA, or PS, polymer derivatives having a phenolic group, acrylic polymer, imide-based polymer, arylether-based polymer, amide-based polymer, fluorine-based polymer, p-xylene-based polymer, vinyl alcohol-based polymer, and the like.

A contact metal CM and/or various wirings, and the like may be arranged between the first organic insulating layer 117 and the second organic insulating layer 118, thereby enabling relatively high integration. The contact metal CM and other wirings may include, for example, a metal material including Mo, Al, Cu, Ti, and the like, and may be formed in a multilayer or single layer including the above material.

The display element layer LEL may be arranged on the second organic insulating layer 118. The display element layer LEL may include the first display element LE1, the second display element LE2, and a pixel defining layer 119.

The first display element LE1 and the second display element LE2 may each include an organic light-emitting diode OLED. The organic light-emitting diode OLED may include a stack structure of the pixel electrodes 121 and 121′, light-emitting layers 122b and 122b′, and a counter electrode 123.

The pixel electrodes 121 and 121′ may include a conductive oxide such as ITO, IZO, ZnO, In₂O₃, IGO, IZGO, or AZO. The pixel electrodes 121 and 121′ may include a reflective film including Ag, Mg, Al, Pt, Pd, Au, Ni, Nd, Ir, Cr, or compounds thereof. For example, the pixel electrodes 121 and 121′ may have a structure in which films including ITO, IZO, ZnO, or In₂O₃ above/below the above-described reflective film. In this case, the pixel electrodes 121 and 121′ may have a stack structure of ITO/Ag/ITO.

The pixel defining layer 119 may be arranged on the second organic insulating layer 118, and may cover the edges of the pixel electrodes 121 and 121′. The pixel defining layer 119 may have an opening OP that exposes the center portions of the pixel electrodes 121 and 121′. For example, the pixel defining layer 119 may include a first opening OP1 that exposes the center portion of the pixel electrode 121 of the first display element LE1 and a second opening OP2 that exposes the center portion of the pixel electrode 121′ of the second display element LE2. An emission area, that is, a pixel, of the organic light-emitting diode OLED may be defined by the opening OP. In other words, the size and shape of the first pixel PX1 may be defined by the first opening OP1, and the size and shape of the second pixel PX2 may be defined by the second opening OP2.

The pixel defining layer 119 may increase a distance between the edges of the pixel electrodes 121 and 121′ and the counter electrode 123 above the pixel electrodes 121 and 121′, thereby preventing or reducing instances of generation of an arc and the like between the edges of the pixel electrodes 121 and 121′. The pixel defining layer 119 may include an organic insulating material such as polyimide, polyamide, acryl resin, BCB, HMDSO, phenol resin, and the like, by a method such as spin coating and the like.

The light-emitting layers 122b and 122b′ formed corresponding to the pixel electrodes 121 and 121′ may be arranged in the opening OP of the pixel defining layer 119. The light-emitting layers 122 and 122b′ may include a polymer material or a low molecular weight material and may emit red, green, blue, or white light.

An organic functional layer 122e may be arranged above and/or below the light-emitting layers 122 and 122b′. The organic functional layer 122e may include a first functional layer 122a and/or a second functional layer 122c. The first functional layer 122a or the second functional layer 122c may be omitted.

The first functional layer 122a may be arranged below the light-emitting layers 122 and 122b′. The first functional layer 122a may be a single layer or multilayer including organic material. The first functional layer 122a may be a hole transport layer (HTL) that has a single layer structure. Alternatively, the first functional layer 122a may include a hole injection layer (HIL) and a hole transport layer (HTL). The first functional layer 122a may integrally formed to correspond to the first display elements LE1 and the second display elements LE2 respectively provided in the first display area DA1 and the second display area DA2.

The second functional layer 122c may be arranged above the light-emitting layers 122 and 122b′. The second functional layer 122c may be a single layer or multilayer including an organic material. The second functional layer 122c may include an electron transport layer (ETL) and/or an electron injection layer (EIL). The second functional layer 122c may be integrally formed to correspond to the first display elements LE1 and the second display elements LE2 respectively provided in the first display area DA1 and the second display area DA2.

The counter electrode 123 may be arranged on the second functional layer 122c. The counter electrode 123 may include a conductive material having a low work function. For example, the counter electrode 123 may include a (semi-)transparent layer including Ag, Mg, Al, Pt, Pd, Au, Ni, Nd, Ir, Cr, lithium (Li), Ca, an alloy thereof, and the like. Alternatively, the counter electrode 123 may further include a layer such as ITO, IZO, ZnO, or In₂O₃ on the (semi-)transparent layer including the above-described material. The counter electrode 123 may be integrally formed to correspond to the first display elements LE1 and the second display elements LE2 respectively provided in the first display area DA1 and the second display area DA2.

A stack structures from the pixel electrode 121 to the counter electrode 123 formed in the first display area DA1 may form the organic light-emitting diode OLED, as the first display element LE1. A stack structures from the pixel electrode 121′ to the counter electrode 123 formed in the second display area DA2 may form the organic light-emitting diode OLED, as the second display element LE2.

In some embodiments, a capping layer 150 may be formed on the counter electrode 123. The capping layer 150 may be a layer provided to protect the counter electrode 123 and simultaneously increase light extraction efficiency. The capping layer 150 may include an organic material. Alternatively, the capping layer 150 may include LiF. Alternatively, the capping layer 150 may include an inorganic insulating material such as SiO₂ or SiNₓ.

According to some embodiments, the thin film encapsulation layer TFEL may be arranged on the display element layer LEL. The thin film encapsulation layer TFEL may include at least one inorganic encapsulation layer and at least one organic encapsulation layer. According to some embodiments, the thin film encapsulation layer TFEL may include the first inorganic encapsulation layer 131 and the second inorganic encapsulation layer 133, and the organic encapsulation layer 132 therebetween.

For example, the first inorganic encapsulation layer 131 and the second inorganic encapsulation layer 133 may include one or more inorganic insulating materials such as SiO₂, SiNₓ, SiOₓN_{y}, Al₂O₃, TiO₂, or Ta₂O₅, and may be formed by a chemical vapor deposition (CVD) method and the like. The organic encapsulation layer 132 may include a polymer-based material. The polymer-based material may include silicon resin, acrylic resin, epoxy resin, polyimide, polyethylene, and the like. The first inorganic encapsulation layer 131, the organic encapsulation layer 132, and the second inorganic encapsulation layer 133 may be integrally formed to cover the first display area DA1 and the second display area DA2.

The first display element LE1 and the first pixel circuit PC1 that drives the same may be all located in the first display area DA1, and the first display element LE1 and the first pixel circuit PC1 may be arranged to overlap each other. The pixel electrode 121 of the first display element LE1 may be electrically connected to the first pixel circuit PC1 through a first contact metal CM1.

According to some embodiments, while the second display element LE2 is located in the second display area DA2, the second pixel circuit PC2 that drives the second display element LE2 may be located in the peripheral area PA. The connection wiring CWL may be provided to electrically connect the second display element LE2 and the second pixel circuit PC2 to each other. The connection wiring CWL may extend from the second display area DA2 to the peripheral area PA, and at least part thereof may be arranged in the second display area DA2.

The connection wiring TWL may include, for example, a TCO. For example, the connection wiring TWL may include a conductive oxide such as ITO, IZO, ZnO, In₂O₃, IGO, IZGO, or AZO. Accordingly, even when the connection wiring CWL is arranged in the transmission area TA of the second display area DA2, the deterioration of light transmittance of the transmission area TA may be reduced.

According to some embodiments, the connection wiring CWL may be arranged on the interlayer insulating layer 115. The connection wiring CWL may be covered by the first organic insulating layer 117. According to some embodiments, a second contact metal CM2 and the bridge wiring BWL may be arranged on the first organic insulating layer 117. The second contact metal CM2 and the bridge wiring BWL may be covered by the second organic insulating layer 118. The second contact metal CM2 may be connected to the connection wiring CWL through a second contact hole CNT2, and the bridge wiring BWL may be connected to the connection wiring CWL through a third contact hole CNT3. The connection wiring CWL may be electrically connected to the pixel electrode 121′ of the second display element LE2 through the second contact metal CM2, and furthermore, may be electrically connected to the second pixel circuit PC2 through the bridge wiring BWL located in the peripheral area PA.

The first conductive layer CL1 and a second conductive layer CL2 apart from each other may be arranged on the interlayer insulating layer 115 in the first display area DA1. A third conductive layer CL3 may be arranged on the first organic insulating layer 117.

The first conductive layer CL1 may be a conductive layer that is electrically connected through a first contact hole CNT1 to the third conductive layer CL3 which is on an upper layer of the first conductive layer CL1. The second conductive layer CL2 may be a conductive layer that is not connected to a conductive layer arranged on an upper layer of the second conductive layer CL2. In FIG. 5, the drain electrode DE may be the first conductive layer CL1, and the source electrode SE may be the second conductive layer CL2. The first contact metal CM1 may be the third conductive layer CL3.

According to some embodiments, a first protective layer PVX1 may be arranged on the first conductive layer CL1. The first protective layer PVX1 may include the same material as the connection wiring CWL. The first protective layer PVX1 may include a TCO. For example, the first protective layer PVX1 may include a conductive oxide such as ITO, IZO, ZnO, In₂O₃, IGO, IZGO, or AZO.

The first protective layer PVX1 may be configured to prevent or reduce damage to a surface, for example, an upper surface, of the first conductive layer CL1 during s process. When the upper surface of the first conductive layer CL1 is damaged, the resistance of the first conductive layer CL1 or the contact resistance of the third conductive layer CL3 connected to the first conductive layer CL1 may be increased. According to some embodiments, as the first protective layer PVX1 of a conductive material is provided, the damage of the first conductive layer CL1 may be prevented or reduce and additionally, a resistance value of the first conductive layer CL1 may be reduced.

The first protective layer PVX1 may be in direct contact with the upper surface of the first conductive layer CL1, and may at least partially overlap the first contact hole CNT1 defined in the first organic insulating layer 117. The third conductive layer CL3 arranged on the first organic insulating layer 117 may be connected to the first protective layer PVX1 through the first contact hole CNT1.

According to some embodiments, the thickness of the first protective layer PVX1 may be about 300 Å to 800 Å. The thickness of the first conductive layer CL1 may be about 5000 Å to 8000 Å. The first conductive layer CL1 and the first protective layer PVX1 may each have a side surface tapered with respect to the upper surface of the substrate 100. The tapered side surface may be inclined by about 40 to 80 degrees with respect to the upper surface of the substrate 100.

According to some embodiments, a phase compensation layer PSC may be at least partially arranged in the second display area DA2 and may overlap the connection wiring CWL on a plane. In other words, when viewed from a direction perpendicular to one surface of the substrate 100 (e.g., in a plan view), the connection wiring CWL and the phase compensation layer PSC may be arranged to overlap each other. For example, the connection wiring CWL and the phase compensation layer PSC may be patterned to have the same shape on a plane.

According to some embodiments, the phase compensation layer PSC may be arranged below the connection wiring CWL. For example, the phase compensation layer PSC may be provided between the interlayer insulating layer 115 and the connection wiring CWL.

As such, as the phase compensation layer PSC is provided, the deterioration of performance of the electronic component 40 (see FIG. 2) arranged in the second display area DA2 may be prevented or reduced, which is described below in more detail with reference to FIG. 6.

Referring to FIG. 6, the phase compensation layer PSC may overlap the connection wiring CWL and may be arranged below the connection wiring CWL. According to some embodiments, the phase compensation layer PSC may include an inorganic insulating material. For example, the phase compensation layer PSC may include at least one of SiO₂, SiNₓ, or silicon carbon nitride (SiCN).

According to some embodiments, a refractive index n1 of the connection wiring CWL may be greater than a refractive index n0 of the first organic insulating layer 117. In the specification, the refractive index may mean a relative refractive index. For example, the refractive index n0 of the first organic insulating layer 117 may be about 1.4 to about 1.8 with respect to a 550 nm wavelength. For example, the refractive index n0 of the first organic insulating layer 117 may be about 1.65. The refractive index n1 of the connection wiring CWL may be about 1.8 to about 2.2 with respect to a 550 nm wavelength. For example, the refractive index n1 of the connection wiring CWL may be about 1.91.

According to some embodiments, a refractive index n2 of the phase compensation layer PSC may be less than the refractive index n0 of the first organic insulating layer 117. For example, the refractive index n2 of the phase compensation layer PSC may be about 1.3 to about 1.8 with respect to a 550 nm wavelength. For example, the refractive index n2 of the phase compensation layer PSC may be about 1.47.

Of light passing through the second display area DA2, first light L1 may pass through an area where the connection wiring CWL is arranged, and the second light L2 may pass through an area where the connection wiring CWL is not arranged. Due to a difference between the refractive index n1 of the connection wiring CWL and the refractive index n0 of the first organic insulating layer 117 covering the connection wiring CWL, a phase difference may be generated between the first light L1 and the second light L2 and rotation phenomenon may be generated. Due to the diffraction phenomenon, the performance of the electronic component 40 (see FIG. 2) may be deteriorated. For example, when the electronic component 40 is an image pickup device such as a camera, due to the diffraction phenomenon according to a phase difference between the first light L1 and the second light L2, a problem such as a flare phenomenon may be generated.

To solve the above problem, the display device 10 according to some embodiments may include low the phase compensation layer PSC that overlaps the connection wiring CWL and has the refractive index n2 that is less than the refractive index n0 of the first organic insulating layer 117. The phase compensation layer PSC may compensate for the phase of the first light L1 such that the first light L1 and the second light L2 have substantially the same phase. In other words, the light incident on the second display area DA2 may have substantially the same phase regardless of passing through the connection wiring CWL. Accordingly, a light diffraction phenomenon may be reduced, and the deterioration of performance of the electronic component 40 may be prevented or reduced.

According to some embodiments, when the refractive index n1 of the connection wiring CWL and the refractive index n2 of the phase compensation layer PSC are different from each other, a thickness t1 of the connection wiring CWL and a thickness t2 of the phase compensation layer PSC may be different from each other. The thickness t2 of the phase compensation layer PSC may be provide such that, in the second display area DA2, the light passing through the area where the connection wiring CWL is arranged and the light passing through the area where the connection wiring CWL is not arranged have the same phase (or substantially the same phase). In other words, the thickness t2 of the phase compensation layer PSC may be determined to allow the first light L1 and the second light L2 to have the same phase. In an example, the thickness t2 of the phase compensation layer PSC may be provided such that an optical path difference between the first light L1 and the second light L2 is an integer multiple of a wavelength. For example, when the refractive index n2 of the phase compensation layer PSC is less than the refractive index n1 of the connection wiring CWL, the thickness t2 of the phase compensation layer PSC may be greater than the thickness t1 of the connection wiring CWL. According to some embodiments, when the connection wiring CWL has the refractive index n1 of about 1.91 and the thickness t1 of about 500 Å, if the phase compensation layer PSC has the refractive index n2 of about 1.47 and the thickness t2 of about 600 Å to 800 Å, the diffraction phenomenon may be reduced.

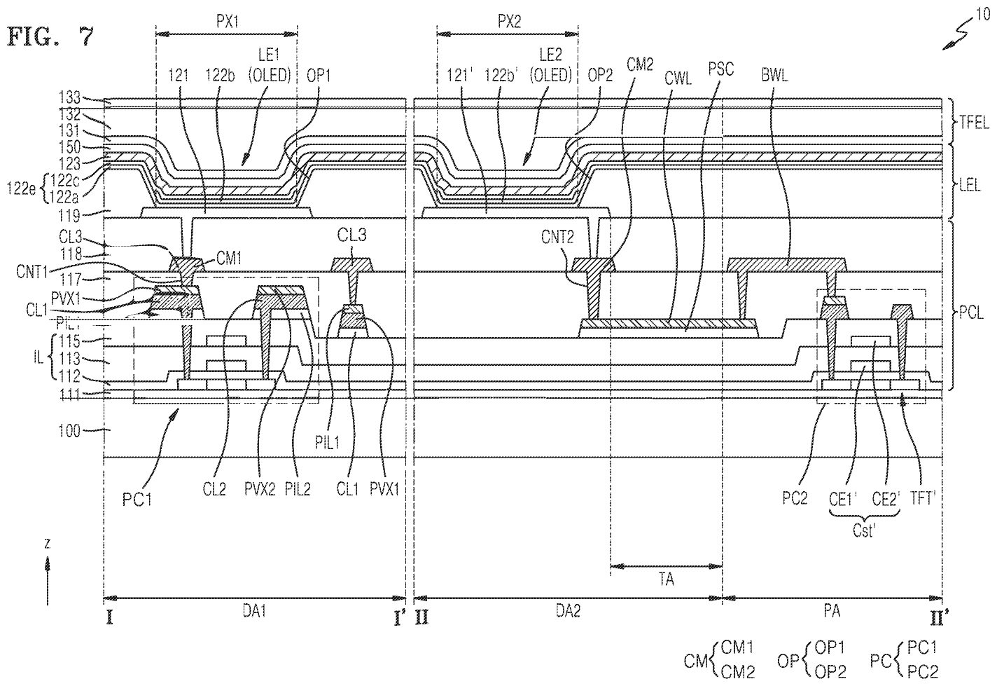

FIG. 7 is a schematic cross-sectional view of part of the display device according to some embodiments. The display device of FIG. 7 may be a modified example of the display device 10 of FIG. 5. As the constituent elements of FIG. 7 that are the same as or similar to the constituent elements described with reference to FIGS. 5 and 6 are indicated by the same reference numerals, differences therebetween are mainly described below.

Referring to FIG. 7, in the display device according to some embodiments, the first pixel circuit PC1 and the first display element LE1 are arranged in the first display area DA1, the second display element LE2 is arranged in the second display area DA2, and the second pixel circuit PC2 is arranged in the peripheral area PA. The second display element LE2 and the second pixel circuit PC2 may be connected to each other through the connection wiring CWL. The first conductive layer CL1 is arranged in the first display area DA1, and the first protective layer PVX1 including the same material as the connection wiring CWL is arranged on the first conductive layer CL1.

According to some embodiments, a first pattern inorganic layer PIL1 may be arranged below the first conductive layer CL1, and a second pattern inorganic layer PIL2 may be arranged below the second conductive layer CL2. In other words, the first pattern inorganic layer PIL1 may be arranged between the interlayer insulating layer 115 and the first conductive layer CL1. The second pattern inorganic layer PIL2 may be arranged between the interlayer insulating layer 115 and the second conductive layer CL2.

The first pattern inorganic layer PIL1 may be patterned to be the same as the shape of the first conductive layer CL1. The second pattern inorganic layer PIL2 may be patterned to be the same as the shape of the second conductive layer CL2.

The first pattern inorganic layer PIL1 and the second pattern inorganic layer PIL2 may include the same material as the phase compensation layer PSC. For example, the first pattern inorganic layer PIL1 and the second pattern inorganic layer PIL2 may include at least one of SiO₂, SiNₓ, or SiCN. Although in the drawing the first pattern inorganic layer PIL1, the second pattern inorganic layer PIL2, and the phase compensation layer PSC are illustrated as a separate layer from the interlayer insulating layer 115, the disclosure is not limited thereto. In some embodiments, the first pattern inorganic layer PIL1, the second pattern inorganic layer PIL2, and the phase compensation layer PSC may be integrally formed the interlayer insulating layer 115.

Furthermore, according to some embodiments, a second protective layer PVX2 may be arranged on the second conductive layer CL2. The second protective layer PVX2 may include the same material as the connection wiring CWL. The first protective layer PVX1 and the second protective layer PVX2 may be respectively patterned in the same shapes as the first conductive layer CL1 and the second conductive layer CL2. For example, the area of the upper surface of the first conductive layer CL1 may be the same as the area of a lower surface of the first protective layer PVX1, and the area of an upper surface of the second conductive layer CL2 may be the same as the area of a lower surface of the second protective layer PVX2.

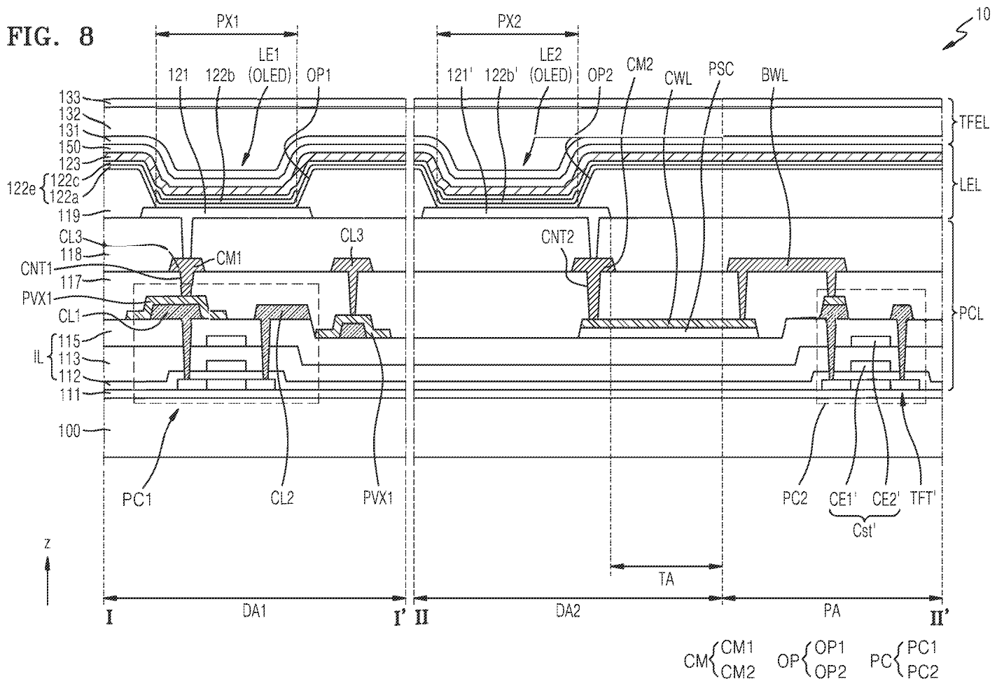

FIG. 8 is a schematic cross-sectional view of part of a display device according to some embodiments. The display device of FIG. 8 may be a modified example of the display device 10 of FIG. 5. As the constituent elements of FIG. 8 that are the same as or similar to the constituent elements described with reference to FIGS. 5 and 6 are indicated by the same reference numerals, differences therebetween are mainly described below.

Referring to FIG. 8, in the display device according to some embodiments, the first pixel circuit PC1 and the first display element LE1 are arranged in the first display area DA1, the second display element LE2 is arranged in the second display area DA2, and the second pixel circuit PC2 is arranged in the peripheral area PA. The second display element LE2 and the second pixel circuit PC2 are connected to each other through the connection wiring CWL. The first conductive layer CL1 is arranged in the first display area DA1, and the first protective layer PVX1 including the same material as the connection wiring CWL is arranged on the first conductive layer CL1.

According to some embodiments, the first protective layer PVX1 may cover a side surface of the first conductive layer CL1. In this case, the area of the first protective layer PVX1 may be greater than the area of the first conductive layer CL1. As the first protective layer PVX1 covers the side surface of the first conductive layer CL1, not only the upper surface, but the side surface of the first conductive layer CL1 may be protected from being damaged.

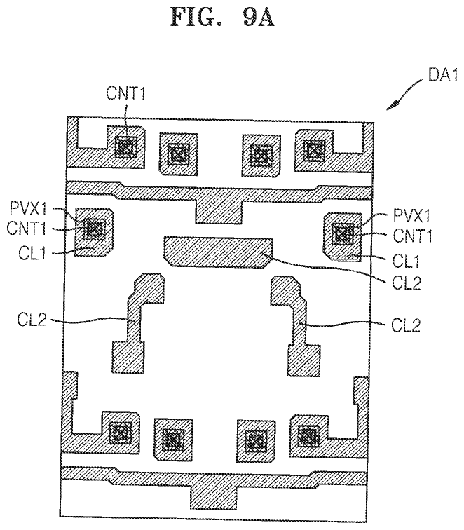

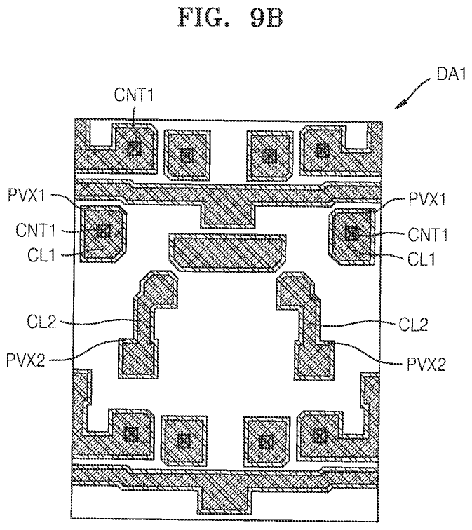

FIGS. 9A and 9B are plan views showing an arrangement relationship of the first conductive layer CL1, the second conductive layer CL2, the first protective layer PVX1, and the second protective layer PVX2 that are arranged in the first display area DA1, according to embodiments.

Referring to FIG. 9A, the first conductive layer CL1 and the second conductive layer CL2 may be arranged on the same layer, for example, the interlayer insulating layer 115 (see FIG. 5). The first conductive layer CL1, as a conductive layer connected to the third conductive layer CL3 (see FIG. 5) through the first contact hole CNT1, may be arranged to overlap the first contact hole CNT1. The first protective layer PVX1 may be arranged above the first conductive layer CL1 to overlap the first contact hole CNT1. The first protective layer PVX1 may be arranged to correspond to the first contact hole CNT1. The first protective layer PVX1 may be provided to be the same as or greater than the size of a lower surface of the first contact hole CNT1.

Although in FIG. 9A the first protective layer PVX1 is illustrated as being arranged only in a part of the first conductive layer CL1, the disclosure is not limited thereto. As illustrated in FIG. 9B, the first protective layer PVX1 may be patterned to be the same as the shape of the first conductive layer CL1. Furthermore, the size of the first protective layer PVX1 may be greater than the size of the first conductive layer CL1. Furthermore, the second protective layer PVX2 may be arranged on the second conductive layer CL2. The second protective layer PVX2 may be patterned in the same shape as the second conductive layer CL2. Furthermore, the second protective layer PVX2 may be variously modified, for example, the size of the second protective layer PVX2 may be greater than the size of the second conductive layer CL2.

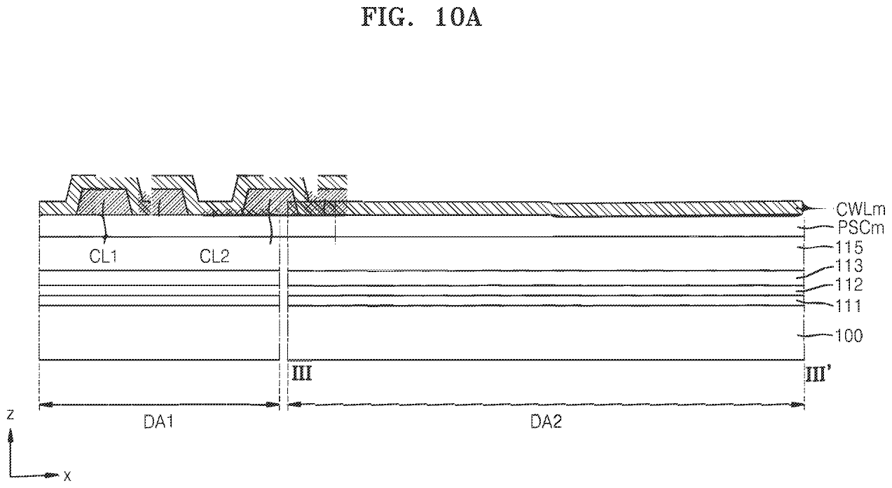

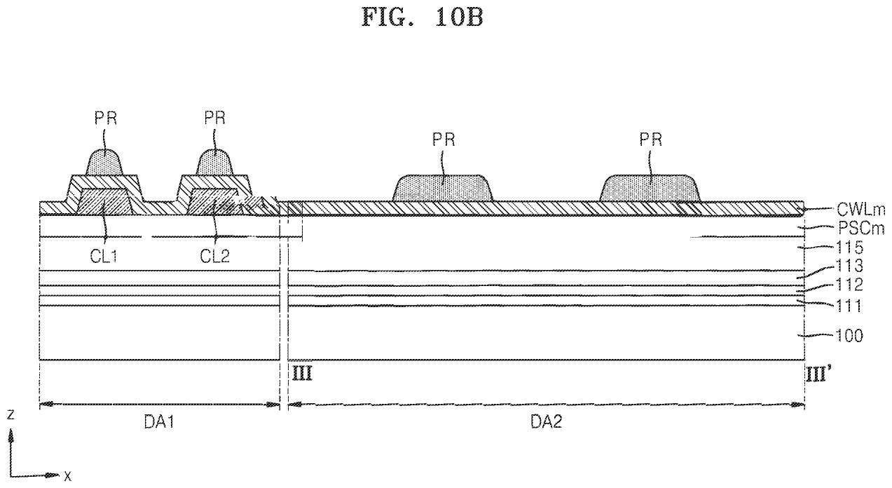

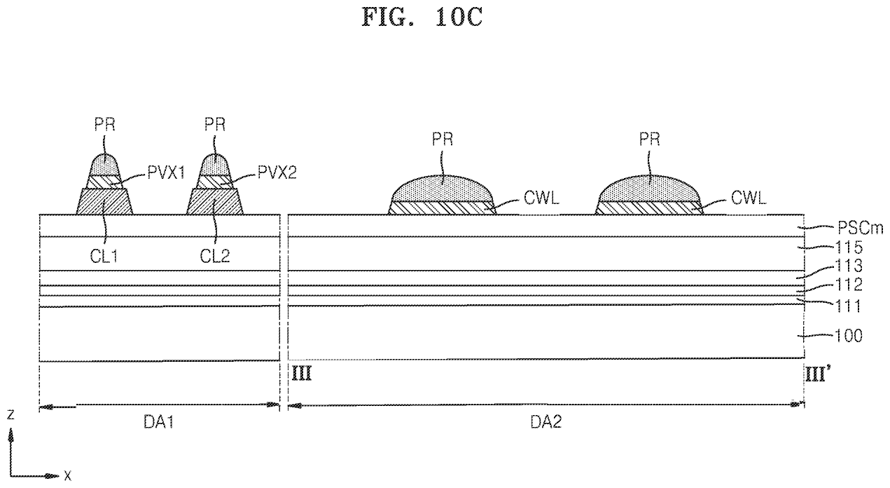

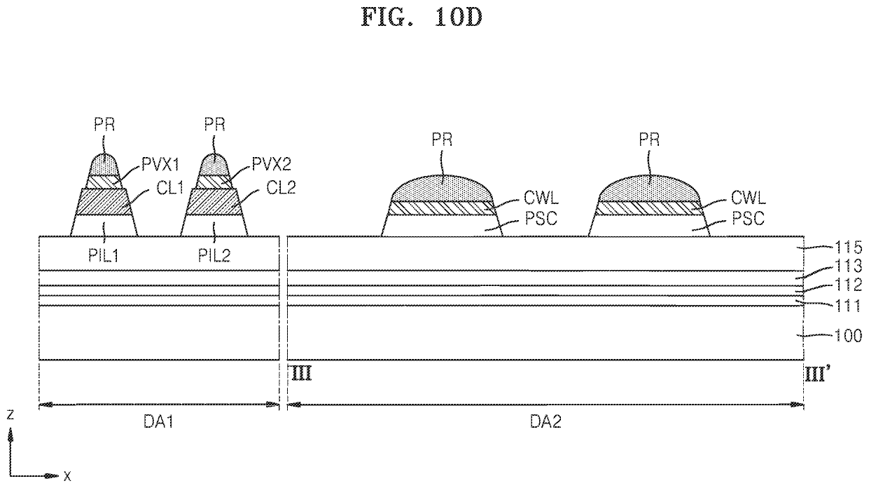

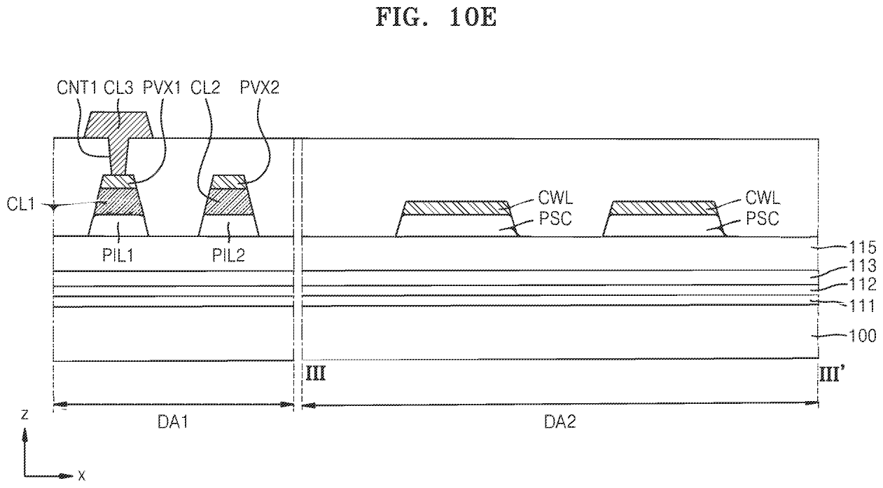

FIGS. 10A to 10E are schematic cross-sectional views showing a process of manufacturing a display device according to some embodiments.

Referring to FIG. 10A, a phase compensation layer-material layer PSCm may be formed on the interlayer insulating layer 115, at least part of the phase compensation layer-material layer PSCm being arranged in the second display area DA2. The phase compensation layer-material layer PSCm may also be arranged in the first display area DA1.

Then, the first conductive layer CL1 and the second conductive layer CL2 arranged in the first display area DA1 may be patterned. In a state in which the first conductive layer CL1 and the second conductive layer CL2 are patterned, a connection wiring-material layer CWLm may be formed on the phase compensation layer-material layer PSCm to cover the first conductive layer CL1 and the second conductive layer CL2.

The phase compensation layer-material layer PSCm and the connection wiring-material layer CWLm may be formed through a coating process, a deposition process, and the like. In the coating process, a method such as spin coating and the like, may be used, and in the deposition process, a chemical vapor deposition (CVD) such as thermochemical vapor deposition (TCVD), plasma enhanced CVD (PECVD), atmospheric pressure CVD (APCVD), and the like, or physical vapor deposition (PVD) such as thermal evaporation, sputtering, e-beam evaporation, and the like may be used.

Referring to FIG. 10B, a photoresist pattern layer PR may form/be formed on the connection wiring-material layer CWLm. The photoresist pattern layer PR may be formed by exposing photoresist through a photomask and developing the same.

Referring to FIG. 10C, the first protective layer PVX1, the second protective layer PVX2, and the connection wiring CWL may be formed by etching the connection wiring-material layer CWLm using the photoresist pattern layer PR as a mask. In this state, the etching may be performed in a wet etching process.

Referring to FIG. 10D, next, the first pattern inorganic layer PIL1, the second pattern inorganic layer PIL2, and the phase compensation layer PSC may be formed by etching the phase compensation layer-material layer PSCm using the photoresist pattern layer PR. In this state, the etching may be performed in a dry etching process. According to some embodiments, as the first conductive layer CL1 and the second conductive layer CL2 may be damaged by a gas used in a dry etching process, the first protective layer PVX1 and/or the second protective layer PVX2 are adopted. In other words, as the first protective layer PVX1 is provided on the first conductive layer CL1, in the dry etching process, the upper surface of the first conductive layer CL1 may not be damaged.

Referring to FIG. 10E, the photoresist pattern layer PR is removed, and the first organic insulating layer 117 may be formed on the interlayer insulating layer 115 to cover the phase compensation layer PSC and the connection wiring CWL. The first organic insulating layer 117 may include the first contact hole CNT1 that at least partially exposes the first conductive layer CL1. The first organic insulating layer 117 may be formed by a method such as spin coating and the like. Next, the third conductive layer CL3 that is connected to the first protective layer PVX1 through the first contact hole CNT1 may be formed on the first organic insulating layer 117.

As described above, in the display device and the electronic device according to one or more embodiments, as no pixel circuit is arranged in an area where components are arranged, a large transmission area may be secured, thereby improving transmittance.

Furthermore, the display device and the electronic device according to the embodiments includes a protective layer for protecting a conductive layer arranged in a first display area, thereby reducing damage of the conductive layer.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a substrate including a first area, a second area, and a third area, the first area and the second area are a display area;
a first pixel circuit in the first area, and a first display element connected to the first pixel circuit;
a second display element in the second area;
a second pixel circuit in the third area;
a connection wiring between the substrate and the second display element and connecting the second display element to the second pixel circuit;
a first conductive layer in the first area; and
a first protective layer including a same material as the connection wiring and on the first conductive layer.

2. The display device of claim 1, further comprising:
a second conductive layer in the first area and on a same layer as the first conductive layer;
an insulating layer covering the first conductive layer and the second conductive layer; and
a third conductive layer on the insulating layer and connected to the first protective layer through a first contact hole defined in the insulating layer.

3. The display device of claim 2, wherein the first contact hole overlaps the first protective layer.

4. The display device of claim 2, further comprising a second protective layer including a same material as the connection wiring and on the second conductive layer.

5. The display device of claim 1, wherein an area of a lower surface of the first protective layer is a same as an area of an upper surface of the first conductive layer.

6. The display device of claim 1, wherein the first protective layer covers a side surface of the first conductive layer.

7. The display device of claim 1, further comprising:
an organic insulating layer above the connection wiring; and
a phase compensation layer below the connection wiring,
wherein a refractive index of the phase compensation layer is less than a refractive index of the organic insulating layer.

8. The display device of claim 7, wherein the phase compensation layer is patterned in a shape of the connection wiring.

9. The display device of claim 7, wherein a thickness of the phase compensation layer is greater than a thickness of the connection wiring.

10. The display device of claim 7, further comprising a pattern inorganic layer below the first conductive layer,
wherein the pattern inorganic layer includes a same material as the phase compensation layer.

11. The display device of claim 2, wherein an area of the first protective layer is less than an area of the first conductive layer and greater than an area of a lower surface of the first contact hole.

12. The display device of claim 1, wherein the first protective layer is patterned in a shape of the first conductive layer.

13. The display device of claim 1, further comprising:
a second conductive layer in the first area and on a same layer as the first conductive layer; and
a second protective layer on the second conductive layer,
wherein the second protective layer is patterned in a shape of the second conductive layer.

14. The display device of claim 1, wherein a thickness of the first protective layer is less than a thickness of the first conductive layer.

15. An electronic device comprising:
a display device including a first area, a second area, and a third area, the first area and the second area are a display area; and
a component below the display device to correspond to the second area,
wherein the display device comprises:
a substrate;
a first pixel circuit in the first area, and a first display element connected to the first pixel circuit;
a second display element in the second area;
a second pixel circuit in the third area;
a connection wiring between the substrate and the second display element and connecting the second display element to the second pixel circuit;
a first conductive layer in the first area; and
a first protective layer including a same material as the connection wiring and on the first conductive layer.

16. The electronic device of claim 15, further comprising:
a second conductive layer in the first area and in a same layer as the first conductive layer;
an insulating layer covering the first conductive layer and the second conductive layer; and
a third conductive layer on the insulating layer and connected to the first protective layer through a first contact hole defined in the insulating layer.

17. The electronic device of claim 16, wherein the first contact hole overlaps the first protective layer.

18. The electronic device of claim 16, further comprising a second protective layer including a same material as the connection wiring and on the second conductive layer.

19. The electronic device of claim 15, wherein an area of a lower surface of the first protective layer is a same as an area of an upper surface of the first conductive layer.

20. The electronic device of claim 15, further comprising:
an organic insulating layer above the connection wiring; and
a phase compensation layer below the connection wiring,
wherein a refractive index of the phase compensation layer is less than a refractive index of the organic insulating layer.
